(19) United States
(12) Patent Application Publication
(10) Pub. No.: US 2012/0091313 A1
(43) Pub. Date: Apr. 19, 2012

(54) HOLDER AND USER INTERFACE STRUCTURE FOR HANDHELD MOBILE DEVICE

(76) Inventor: Barrett Cohn, San Francisco, CA (US)

(21) Appl. No.: 13/274,270

(22) Filed: Oct. 14, 2011

Related U.S. Application Data
(60) Provisional application No. 61/393,287, filed on Oct. 14, 2010.

(51) Int. Cl. H05K 7/00

(52) U.S. Cl. 248/682

(57) ABSTRACT

Various embodiments of user interface structures for handheld mobile devices are disclosed. In some embodiments, the user interface structure can include a frame surrounding a carrier portion which secures a mobile device. The shape of the frame can be related to an intended use or application of the mobile device. For example, in embodiments wherein the mobile device is used to play a driving-type video game, the frame can be in the shape of a steering wheel. The structure can be configured to allow the user to grasp and move the frame so as to simultaneously move the handheld mobile device. The structure can further serve as a protective enclosure that can prevent the mobile device from being damaged.

### CROSS-REFERENCE TO RELATED APPLICATION

The present application claims priority to and the benefit of U.S. Provisional Patent Application No. 61/393,287, filed on Oct. 14, 2010 and titled HOLDER AND USER INTERFACE STRUCTURE FOR HANDHELD MOBILE DEVICE, which is incorporated herein by reference in its entirety.

### TECHNICAL FIELD

The following disclosure relates generally to handheld mobile devices and, more particularly, to user interface structures for handheld mobile devices.

### BACKGROUND

Mobile devices, such as cellular telephones, are smaller than ever and run an increasing number of software applications. Many of the devices have an internal orientation-sensing apparatus. The detected orientation is used as a user input in running some applications, such as games, cameras, etc. Because the mobile devices are small and thin, it can be difficult to maintain a grasp on a device while manipulating its orientation as required by the application. If the user attempts to hold the sides of the device, often a portion of the viewing screen may be obscured. There is a risk that the device may be dropped or otherwise damaged when the device is being used or carried.

### BRIEF DESCRIPTION OF THE DRAWINGS

FIG. 1A is a front view of a user interface structure configured in accordance with an embodiment of the disclosure.

FIG. 1B is a front view of the user interface structure of FIG. 1A having a mobile device contained therein.

FIG. 1C is a rear view of the user interface structure of FIG. 1A.

FIG. 1D is a side isometric view of the user interface structure of FIG. 1A.

FIG. 2A is a front view of a user interface structure configured in accordance with an embodiment of the disclosure.

FIG. 2B is a rear view of the user interface structure of FIG. 2A.

FIG. 2C is a rear view of the user interface structure of FIG. 2A having a mobile device contained therein.

FIG. 3 is a front isometric view of a user interface structure configured in accordance with an embodiment of the disclosure.

FIG. 4A is a front view of a user interface structure configured in accordance with an embodiment of the disclosure.

FIG. 4B is a front view of the user interface structure of FIG. 4A having a mobile device contained therein.

FIG. 4C is a rear view of the user interface structure of FIG. 4A.

FIG. 4D is a side isometric view of the user interface structure of FIG. 4A.

FIG. 5A is a front view of a user interface structure configured in accordance with an embodiment of the disclosure.

FIG. 5B is a rear view of the user interface structure of FIG. 5A.

FIG. 5C is a rear view of the user interface structure of FIG. 5A having a mobile device contained therein.

FIG. 6 is a side isometric view of a user interface structure configured in accordance with an embodiment of the disclosure.

Appendix A contains pictures of various embodiments of user interface structures as described herein and forms part of the present disclosure.

### DETAILED DESCRIPTION

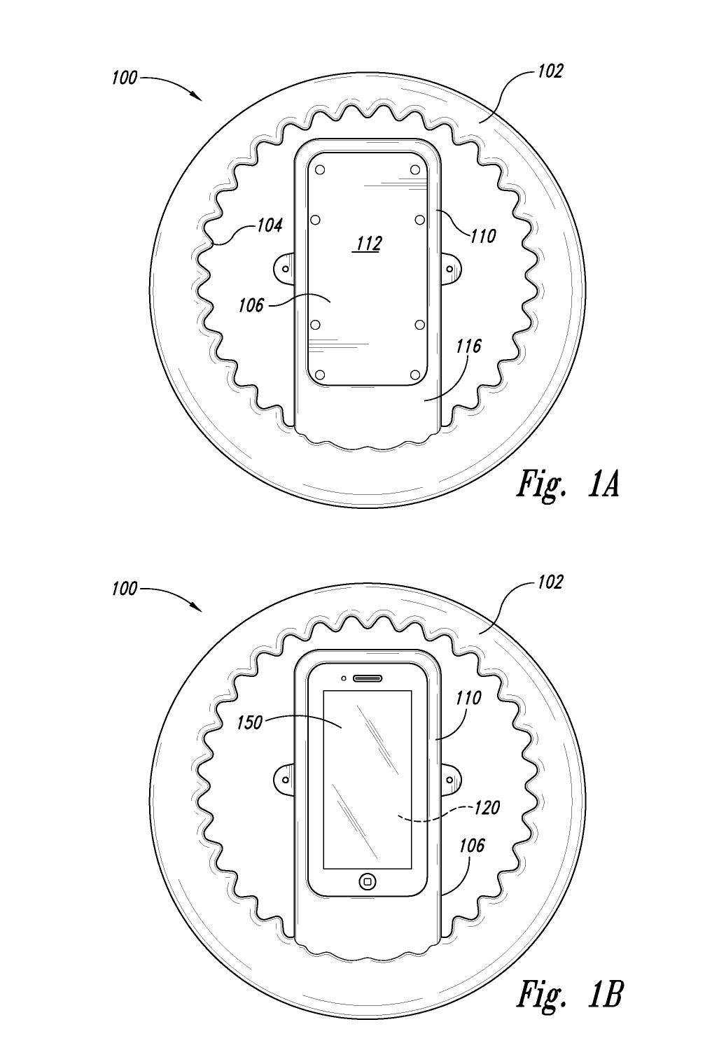

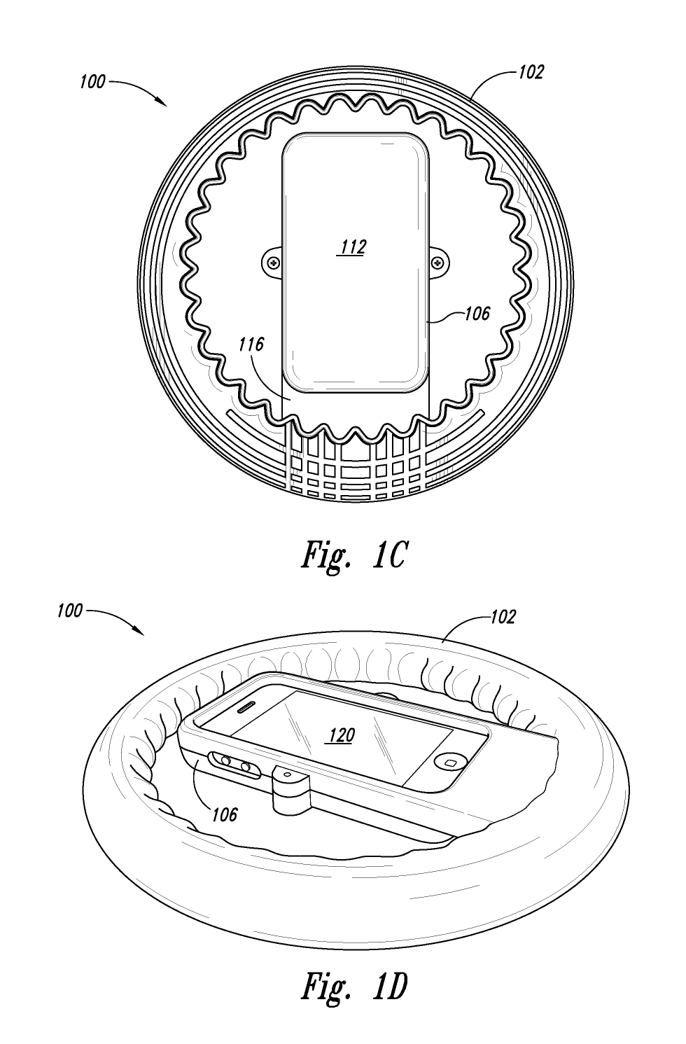

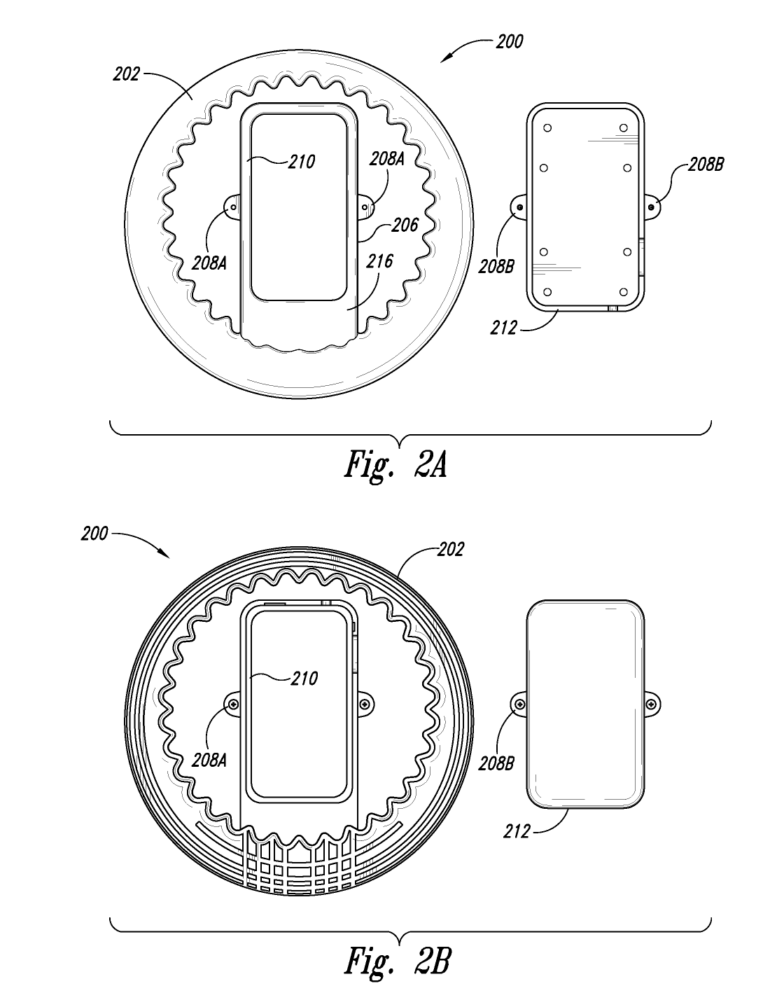

The present disclosure describes various embodiments of user interface structures for handheld mobile devices. In one embodiment, for example, a protective user interface structure can be a selected shape, such as wheel-shaped, and can include a graspable frame that surrounds a carrier for a mobile device. Certain details are set forth in the following description, in FIGS. 1A-6, and in Appendix A to provide a thorough understanding of various embodiments of the disclosure. Other details describing well-known structures and systems often associated with user interface structures, mobile devices, and steering wheels have not been set forth in the following disclosure to avoid unnecessarily obscuring the description of the various embodiments of the disclosure.

Many of the details, dimensions, angles and other features shown in the Figures are merely illustrative of particular embodiments of the disclosure. Accordingly, other embodiments can add other details, dimensions, angles and features without departing from the spirit or scope of the present invention. In addition, those of ordinary skill in the art will appreciate that further embodiments of the invention can be practiced without several of the details described below.

In the Figures, identical reference numbers identify identical, or at least generally similar, elements. To facilitate the discussion of any particular element, the most significant digit or digits of any reference number refers to the Figure in which that element is first introduced. For example, element 110 is first introduced and discussed with reference to FIG. 1.

FIG. 1A is a front view of a protective user interface structure 100 configured in accordance with an embodiment of the disclosure. In the illustrated embodiment, the user interface structure 100 is shaped like a steering wheel. FIG. 1B is a front view of the structure 100 having a mobile device 120 secured therein. FIG. 1C is a rear view of the structure 100. FIG. 1D is a side isometric view of structure 100. Referring to FIGS. 1A-1D together, the structure includes an outer frame 102 and a carrier portion 106 for supporting, enclosing, and/or releasably containing the mobile device 120.

In the illustrated embodiment, the carrier 106 is generally rectangular-shaped to accommodate a generally rectangular-shaped mobile device 120 (FIG. 1B). In other embodiments, the carrier 106 can take on other shapes to accommodate various mobile devices 120 and/or to provide different aesthetic or physical configurations of the structure 100 as a whole. In the illustrated embodiment, the carrier portion 106 protrudes interiorly from the frame 102 via a bridge portion 116, thus occupying a portion of the center of the frame 102. In other embodiments the bridge portion 116 can be bigger or smaller, can entirely surround the carrier 106, can attach to a different side of the carrier 106, or can be comprised of multiple bridge portions which attach the carrier 106 to the frame 102 at a plurality of sites. In yet other embodiments, the bridge 116 and the carrier can project from the frame in a cantilevered fashion without being fully surrounded by the frame.

The mobile device 120 can be a cellular telephone, a personal digital assistant, an audio or visual player, a tablet computer, a digital book or other digital media display device, or other type of mobile electronic device. The mobile device 120 can be secured in the carrier portion 106 by use of one or more clips, latches, screws, fasteners, straps, snaps, hooks, Velcro™, or other mechanisms or by having a shell 110 frictionally surround, frame, or sandwich the mobile device 120. For example, in the illustrated embodiment, the shell 110 surrounds the mobile device 120 and prevents lateral movement. A back plate 112 supports the underside of the mobile device 120 and, along with the shell 110, prevents the device 120 from vertical movement. The shell 110 can, for example, cover a portion of the upper surface of the mobile device 120 to contain the mobile device 120 between the shell 110 and the back plate 112.

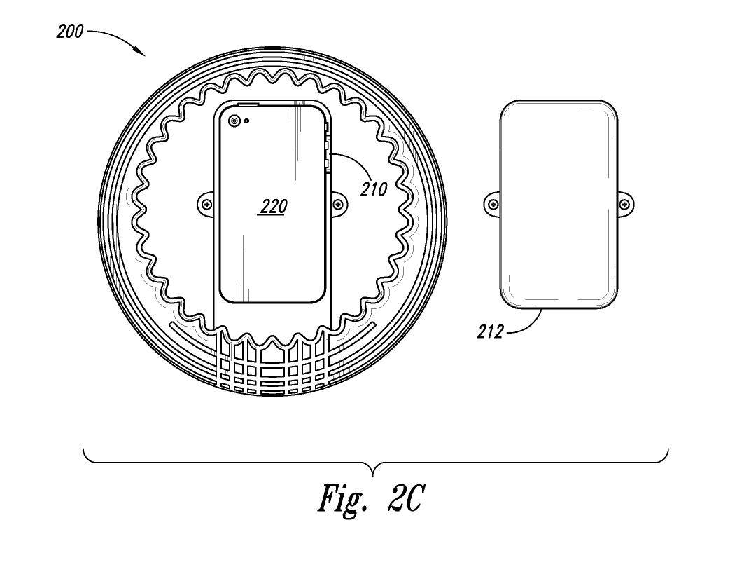

In other embodiments, the back plate 112 need not cover the entire back surface of the mobile device 120. For instance, the back plate 112 may cover a portion of the back surface of the mobile device 120, leaving an opening (not shown) such that the mobile device 120 can be placed in or removed from the carrier 106 via the opening. In some embodiments, as discussed in further detail below with reference to FIGS. 2A-C, the back plate 112 can be removably attached to the shell 110. In still further embodiments, the back plate 112 may be absent altogether, and the mobile device can remain in place by other attachment, retention, or other containment mechanisms.

The delicate nature of electronics equipment may make the mobile device 120 prone to damage. This is especially true when the device 120 is being used by a child or when the device 120 is running an application that requires a great deal of user movement. The carrier 106 of the illustrated embodiment is a sturdy structure that securely contains the mobile device 120 so as to provide protection to the mobile device 120 when the mobile device 120 is being used or carried. The carrier 106 is also configured to provide shock attenuation or absorption if the structure 100 and mobile device 120 are dropped or are otherwise impacted, thereby protecting the mobile device 120 from impact damage. In some embodiments, the carrier 106 can include an optional transparent cover 150 (shown in FIG. 1B) or layer of plastic sheeting or film to protect a surface of the mobile device 120 such as a viewing screen, a button, or input/output interfaces on the device 100. The cover 150 can be removable or can be integral to the carrier 106. The shell 110, back plate 112, and/or viewing screen cover 150 can serve as a secure enclosure that shields the mobile device 120 from external forces and external contaminants, such as water, moisture, dirt, dust, debris, or other contaminant. The graspable nature of the structure 100 (discussed in more detail below), further decreases the risk of causing damage to the device 120 by dropping it.

The structure 100 is configured to allow the user to grasp and move the frame 102 so as to simultaneously move the handheld mobile device 120. The frame 102 can have a shape that relates to an intended use or application of the mobile device 120. For example, in embodiments wherein the mobile device 120 is used to play a driving-type video game, the frame 102 can be in the illustrated shape of a steering wheel. In other embodiments, the frame 102 can have different shapes for different intended uses of the mobile device 120. For example, the frame portion 102 can have a square, oval, rectangular, triangular, or otherwise polygonal or curved exterior shape. Some mobile devices 120 can detect the orientation of the device 120, such as by use of an internal gyroscope, and use this orientation as a user input in running some applications. For example, rotating the mobile device 120 clockwise might translate as a user-inputted right turn in a driving-type video game application. In this example, when the mobile device 120 is positioned in the wheel 100 and the wheel 100 is turned clockwise, the mobile device 120 also turns clockwise and the application registers the right turn.

In the illustrated embodiment, the frame 102 includes grip features 104. The grip features 104 can add friction or graspability to the wheel 110. In the illustrated embodiment, the grip features 104 include a series of elevated ridges. In other embodiments, other types of grip features 104 such as ribbing, texturing, indents or other integral or detachable friction features can be used. In still further embodiments, the grip features 104 can be on a different surface of the structure 100 or can be absent altogether.

The structure 100 can be made of molded plastic, wood, rubber, foam, metal, transparent plastic sheeting, other materials, or a combination of materials. In one embodiment, the entire structure 100 is made of one or more pieces of molded plastic. In another embodiment, the frame 102 is made of molded plastic and the carrier 106 is at least partially made of flexible rubber which stretches to frame the mobile device 120.

FIG. 2A is a front view of a user interface structure 200 configured in accordance with an embodiment of the disclosure. In the illustrated embodiment, the user interface structure 200 takes the form of a steering wheel. FIG. 2B is a rear view of the structure 200. FIG. 2C is a rear view of the structure 200 having a mobile device 220 contained therein. Referring to FIGS. 2A-2C together, the user interface structure 200 includes features generally similar to the user interface structure 100 depicted by FIGS. 1A-1D, including a frame 202, a carrier 206, a shell 210, a back plate 212, and a bridge 216.

In this embodiment, the back plate 212 is detachable from the shell 210. The mobile device 220 is placed in the carrier 206 such that one surface of the device 220 (such as a viewing screen) is framed by the shell 210. The back plate 212 is attachable to the shell 210 via screws or other connectors in connection portions 208A, 208B in the shell 210 and back plate 212 portions respectively. The back plate 212 and shell 210 thus sandwich and secure the mobile device 220 in the carrier 206. In other embodiments, the back plate 212 attaches to the shell 210 via other attachment mechanisms, such as clips, snaps, straps, hinges, fasteners, latches, hooks, Velcro™ or other quick-release mechanisms.

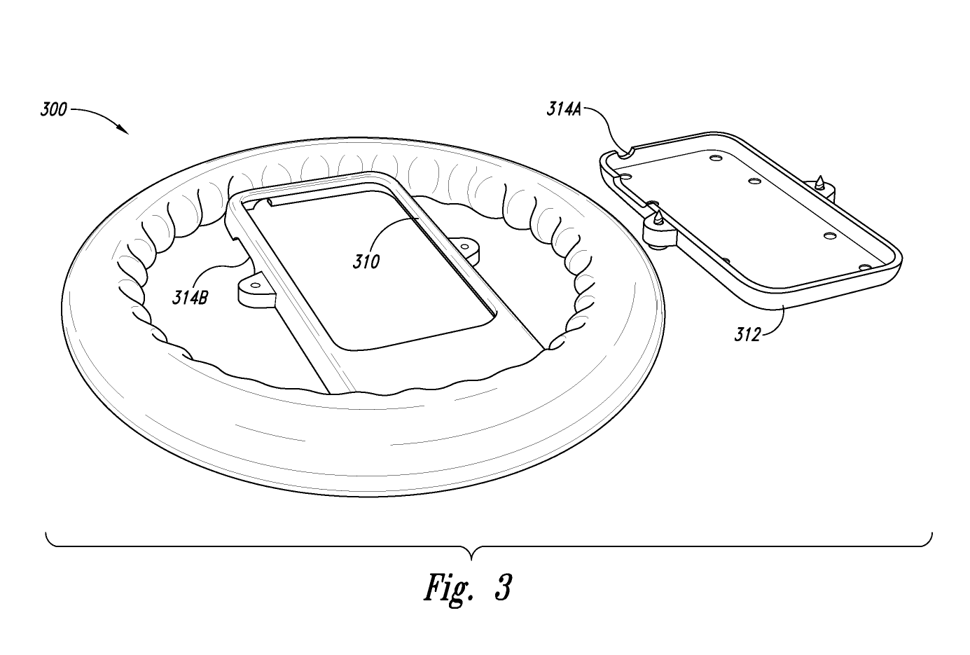

FIG. 3 is a front isometric view of a user interface structure 300 configured in accordance with an embodiment of the disclosure. The user interface structure 300 includes features similar to the user interface structures 100, 200 depicted by FIGS. 1A-1D and 2A-2C respectively. The structure 300 further includes apertures 314A and 314B in a back plate 312 and shell 310 respectively. These apertures 314A, 314B can be configured to provide open access to input/output features of a mobile device (not shown) while the device is secured in the structure 300. For example, the apertures 314A and 314B can allow for user access to input/output connecters for audio or video, batteries, expansion packs, memory cards, antennas, wireless cards, or other accessories. In other embodiments, there may be more or fewer apertures 314A, 314B and they may be in different locations on the structure 300.

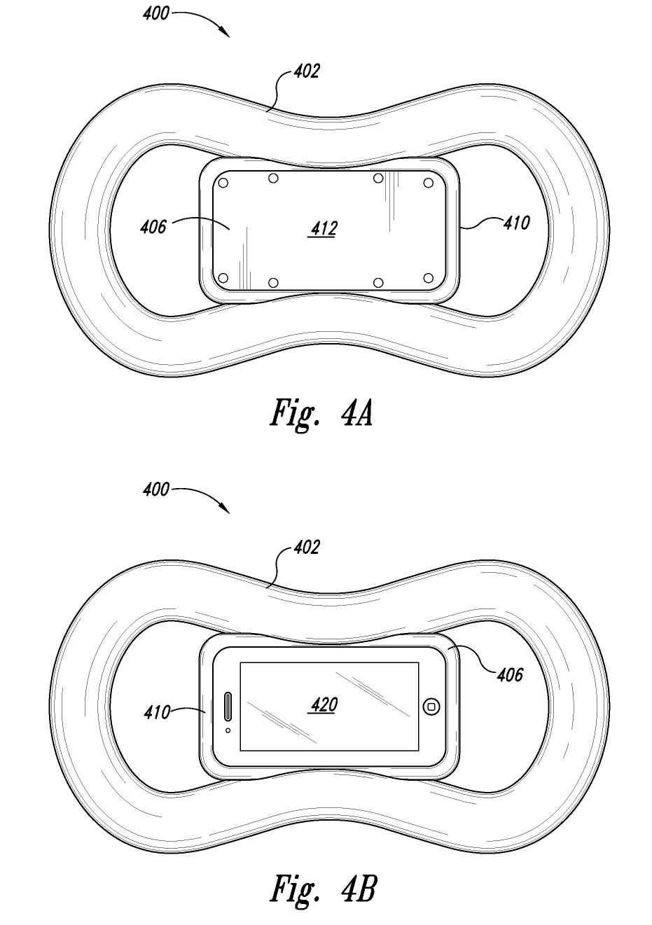

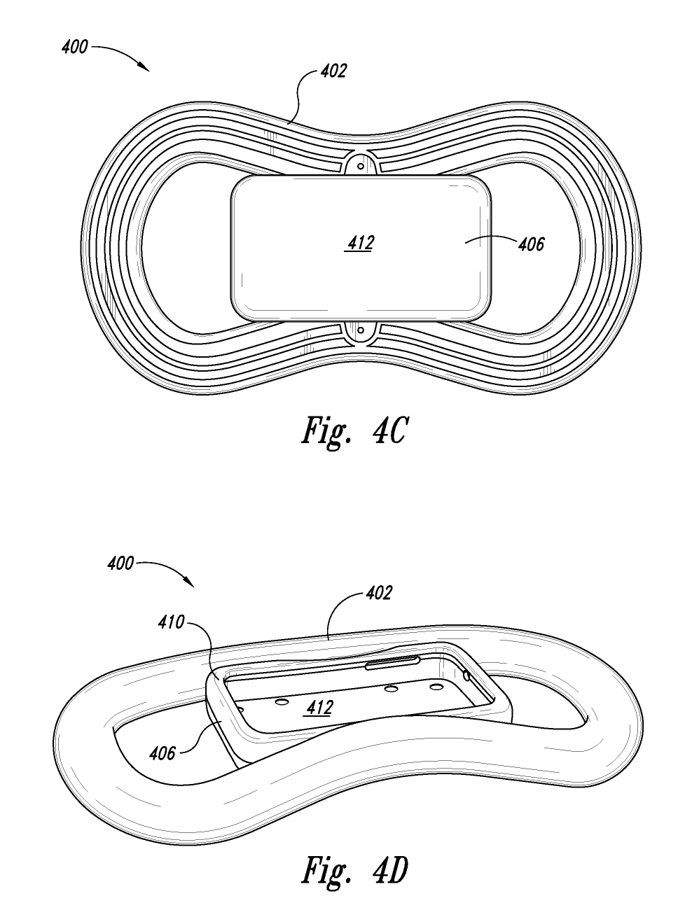

FIG. 4A is a front view of a user interface structure 400 configured in accordance with an embodiment of the disclosure. In the illustrated embodiment, the user interface structure 400 takes the form of a double-handle interface structure configured to receive the mobile device between the handle portions. FIG. 4B is a front view of the structure 400 having a mobile device 420 contained therein. FIG. 4C is a rear view of structure 400. FIG. 4D is a side isometric view of the structure 400. Referring to FIGS. 4A-4D together, the user interface structure 400 includes features similar to the user interface structure 100 depicted by FIGS. 1A-1D, including a frame 402, a carrier 406, a shell 410, and a back plate 412. In this embodiment, the carrier 406 can be attached directly to the shell 410 without use of a bridge portion.

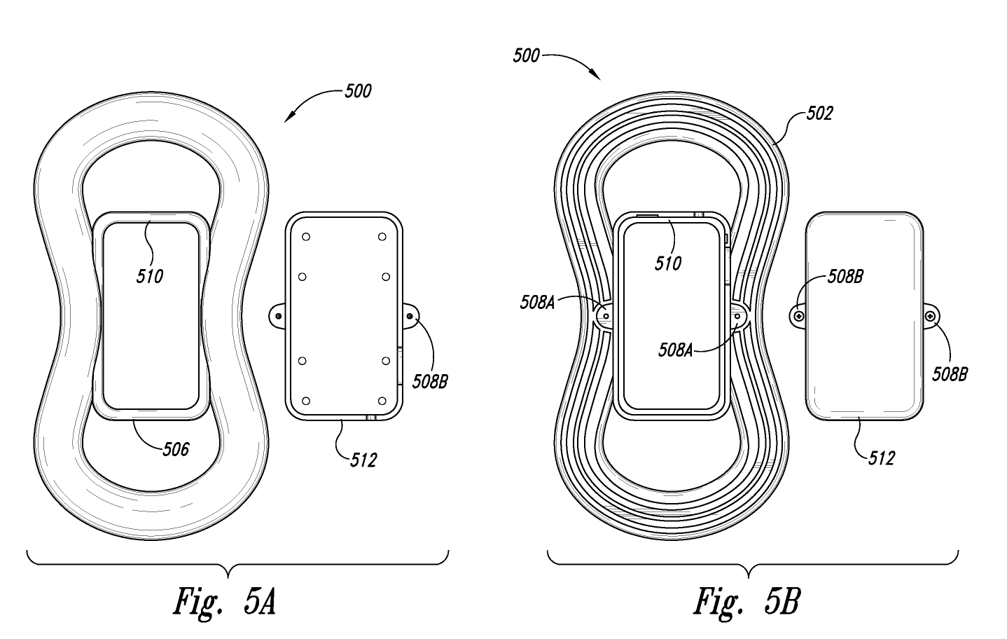

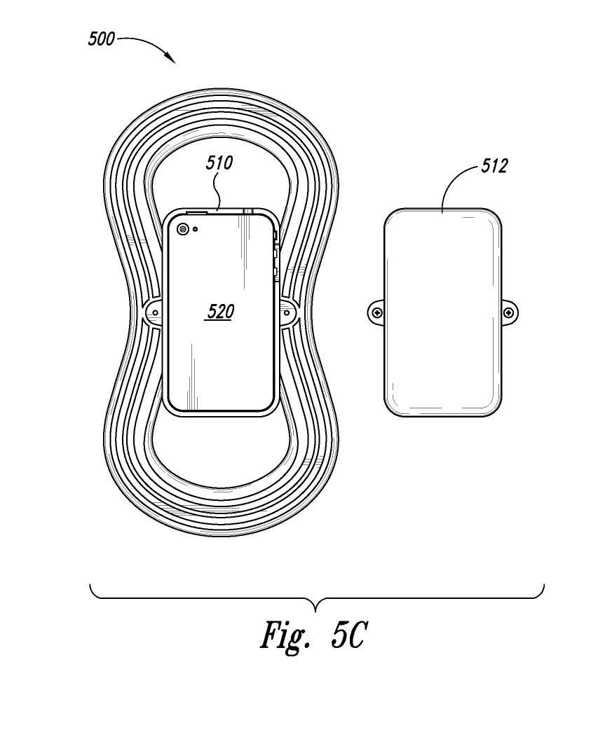

FIG. 5A is a front view of a user interface structure 500 configured in accordance with an embodiment of the disclosure. FIG. 5B is a rear view of the structure 500. FIG. 5C is a rear view of the structure 500 of FIG. 5A having a mobile device 520 contained therein. Referring to FIGS. 5A-5C together, the user interface structure 500 includes features generally similar to the user interface structure 400 depicted by FIGS. 4A-4D. In this embodiment, a back plate 512 is detached from a shell 510. The mobile device 520 can be placed in the carrier 506 such that a surface of the device 520 (such as a viewing screen) is framed by the shell 510. The back plate 512 is attachable to the shell 510 via screws in connection portions 508A, 508B in the frame 510 and back plate 512 portions respectively. The back plate 512 and shell 510 thus sandwich and secure the mobile device 520. In other embodiments, the back plate 512 attaches to the frame 510 via other attachment mechanisms, such as clips, snaps, fasteners, hinges, latches, straps, hooks, Velcro™, or other quick release mechanisms.

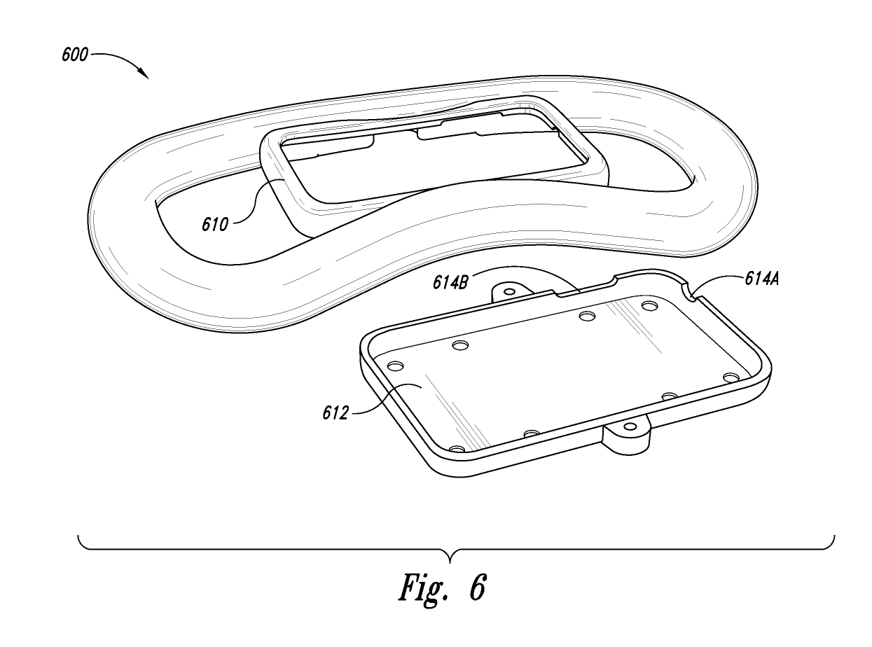

FIG. 6 is a side isometric view of a user interface structure 600 configured in accordance with an embodiment of the disclosure. The user interface structure 600 includes several features similar to the user interface structures 400, 500 depicted by FIGS. 4A-4D and 5A-5C respectively, such as a shell 610 and a back plate 612. The structure 600 further includes apertures 614A and 614B in the back plate 612. These apertures 614A, 614B can be configured to provide open access to input/output features of a mobile device (not shown) while the device is secured in the structure 600. For example, the apertures 614A and 614B can allow for user access to input/output connecters for audio or video, batteries, expansion packs, memory cards, antennas, wireless cards, or other accessories. In other embodiments, there may be more or fewer apertures 614A, 614B and they may be in different locations on the structure 600.

From the foregoing, it will be appreciated that specific embodiments of the invention have been described herein for purposes of illustration, but that various modifications may be made without deviating from the spirit and scope of the various embodiments of the invention. Further, while various advantages associated with certain embodiments of the invention have been described above in the context of those embodiments, other embodiments may also exhibit such advantages, and not all embodiments need necessarily exhibit such advantages to fall within the scope of the invention. Accordingly, the invention is not limited, except as by the appended claims.

I/We claim:

1. A user interface structure for holding an electronic handheld mobile device, the structure comprising:
a graspable outer frame surrounding an open interior space; and
a carrier portion protruding interiorly from the outer frame into the open interior space, the carrier portion comprising:
a shell having an open interior window; and
a back plate coupled to the shell, wherein the shell and the back plate are configured to releasably encase the mobile device.

2. The structure of claim 1 wherein the outer frame is generally circular.

3. The structure of claim 1 wherein the shell and the back plate are configured to releasably encase at least one of a cellular telephone, a personal digital assistant, an audio or visual player, a tablet computer, a digital book reader, or a digital media display device.

4. The structure of claim 1 wherein the carrier is generally rectangular-shaped to accommodate a generally rectangular-shaped mobile device.

5. The structure of claim 1, further comprising a transparent cover coupled to the carrier and positioned adjacent to the open interior window.

6. The structure of claim 1, further comprising a plurality of elevated ridges extending interiorly from the outer frame into the open interior space.

7. The structure of claim 1, wherein the structure is at least partially made of a molded plastic.

8. The structure of claim 1 wherein the carrier portion further comprises an aperture in at least one of the shell or the back plate, wherein the aperture is configured to provide access to at least one of an input or output connector, a battery, an antenna, a memory card, or a wireless card.

9. A holder for a mobile telephone, the holder comprising an outer structure at least partially enclosing a central carrier portion and at least one open interior space, wherein:
the carrier portion is attached to the outer structure via one or more bridge portions;
the carrier portion protrudes interiorly from the outer frame; and
the carrier portion is configured to releasably retain the mobile telephone.

10. The holder of claim 9 wherein the outer structure has a generally curved shape.

11. The holder of claim 9, further comprising a viewing screen cover coupled to the carrier portion.

12. The holder of claim 9 wherein the holder is at least partially made of rubber.

13. The holder of claim 9, further comprising one or more fasteners coupled to the carrier portion and configured to releasably retain the mobile device in the carrier portion.

14. The holder of claim 9 wherein the carrier portion comprises a shell and a back plate configured to releasably retain the mobile device, and wherein the shell is releasably coupled to the back plate with one or more fasteners.

15. The holder of claim 9, further comprising a plurality of grip features on the outer structure.

16. The holder of claim 9 wherein the holder is made primarily of molded plastic.

17. A method of using a holder for a mobile device having a viewing screen, the method comprising:
releasably securing the mobile device in a carrier portion of the holder, wherein the carrier portion protrudes into an open interior space framed by an outer structure;
grasping the outer structure; and
modifying input to the mobile device by rotating the outer structure.

18. The method of claim 17, further comprising detecting an orientation of the mobile device.

19. The method of claim 17 wherein rotating the outer structure comprises simultaneously rotating the structure and the mobile device.

20. The method of claim 17, further comprising viewing the viewing screen of the mobile device through a viewing aperture in the carrier.
